(19) United States
(12) Patent Application Publication
(10) Pub. No.: US 2015/0228738 A1
(43) Pub. Date: Aug. 13, 2015

(54) SPLIT-GATE FLASH CELL WITH COMPOSITE CONTROL GATE AND METHOD FOR FORMING THE SAME

(71) Applicant: WaferTech, LLC, Camas, WA (US)

(72) Inventors: Wen-Bin TSAI, Camas, WA (US); Hsin-I LI, Camas, WA (US); Kin Fung LAM, Vancouver, WA (US)

(73) Assignee: WaferTech, LLC, Camas, WA (US)

(21) Appl. No.: 14/175,056

(22) Filed: Feb. 7, 2014

(51) Int. Cl. H01L 29/423; H01L 29/788; H01L 29/66; H01L 27/115

(52) U.S. Cl. CPC H01L 29/42324; H01L 27/11517; H01L 29/788; H01L 29/66825

(57) ABSTRACT

A split-gate flash cell device and method for forming the same are not provided. The split-gate flash cell device includes a floating gate transistor. The floating gate transistor includes a floating gate and a control gate disposed over at least a portion of the floating gate, along a side of the floating gate and over a portion of the substrate adjacent the floating gate. The control gate includes a portion of SiGe material. In some embodiments, the control gate is a composite material with a lower SiGe layer and an upper material layer. The upper material layer is polysilicon or other suitable materials.

### TECHNICAL FIELD

The disclosure relates to semiconductor devices and methods for making the same. More particularly, the disclosure relates to a split-gate flash cell device with improved electrical characteristics, and methods for forming the same.

### BACKGROUND

A flash memory is a non-volatile storage device that can be electrically erased and reprogrammed. Flash memories are commonly used in memory cards, USB flash drives and solid-state drives for general storage and transfer of data between computers and other digital products. Flash memory devices typically store information in an array of memory cells made using floating gate transistors.

A floating gate transistor is a field effect transistor having a structure similar to a conventional MOSFET (metal oxide semiconductor field effect transistor). Floating gate MOSFETs are distinguished from conventional MOSFETs because the floating gate MOSFET transistor is a split gate transistor that includes two gates instead of one. In addition to an upper control gate, a split gate transistor includes an additional floating gate beneath the control gate and above the transistor channel but completely electrically isolated by an insulating layer such as an oxide layer that completely surrounds the floating gate. This electrically isolated floating gate creates a floating node in direct current (DC) operation with a number of inputs or secondary gates such as the control gate, formed above the floating gate and electrically isolated from it. These secondary gates or inputs are only capacitively connected to the floating gate. Because the floating gate is completely surrounded by highly resistive material, i.e. the insulating layer, any charge placed on the floating gate is trapped there and the floating gate remains unchanged for long periods of time until the floating gate MOSFET is erased. Unless erased, the floating gate will not discharge for many years under normal conditions. Fowler-Nordheim Tunneling or other Hot-Carrier injection mechanisms may be used to modify the amount of charge stored in the floating gate, e.g. to erase the floating gate. The programming and erase operations are therefore critical to the operation of floating gate transistors.

The default state of an NOR (“Not Or” electronic logic gate) flash cell is logically equivalent to a binary “one” value because current flows through the channel under application of an appropriate voltage to the control gate when charge is stored in the floating gate. Such a flash cell device can be programmed or set to binary “zero” by applying an elevated voltage to the control gate.

The programming of the control gate is a critical operation. More particularly, it is important to provide a structure in which a known voltage can be applied to sufficiently program the flash cell device without creating device leakage or other problems. It is desirable to program the flash cell as efficiently as possible and without having to use extreme voltages that cause leakage and other problems.

### BRIEF DESCRIPTION OF THE DRAWING

The present disclosure is best understood from the following detailed description when read in conjunction with the accompanying drawing. It is emphasized that, according to common practice, the various features of the drawing are not necessarily to scale. On the contrary, the dimensions of the various features may be arbitrarily expanded or reduced for clarity. Like numerals denote like features throughout the specification and drawing.

FIGS. 1-3 are cross-sectional views of devices at various stages of formation. FIGS. 1-3 illustrate a sequence of processing operations used to form both a split-gate flash cell device and CMOS device according to an embodiment of the disclosure.

FIG. 1 shows a flash memory area and CMOS area after a SiGe film has been formed;

FIG. 2 shows the flash memory area and the CMOS area after a subsequent polysilicon film has been formed;

FIG. 3 shows the flash memory area and CMOS area after the films formed in FIG. 2 have been patterned to form gate electrodes; and

FIG. 4 shows a split-gate flash cell device according to an embodiment of the disclosure, with further details.

### DETAILED DESCRIPTION

Various embodiments of the disclosure provide a split-gate flash cell that includes one or more transistors. The split gate transistors include both a floating gate and a control gate. In various embodiments, the control gate includes silicon-germanium to provide a reduced depletion region in the control gate. In various embodiments, the silicon-germanium is stoichiometric SiGe and in various embodiments, the silicon-germanium represents any of various alloys including any molar ratio of silicon and germanium, as represented by Si₁₋ₓGeₓ. In still other embodiments, other suitable materials that provide a reduced depletion region in the control gate, such as suitable gate electrode metals Al, Ta, TaN, or Pt, are used. The low gate depletion region produces reduced channel resistance.

The reduced channel resistance enables the use of a lower VT to obtain the saturation current, Isat, used for programming. Alternatively, a higher saturation current is achieved for a given applied voltage as a result of the reduced channel resistance and lowered gate depletion according to the disclosure. The use of a lower threshold voltage (V_{T}) leads to a higher drain side voltage (V_{drain}) and therefore a reduced voltage difference between the source and drain regions of the floating gate transistor. This is because Isat of the control gate is proportional to (V_{gs}−V_{T})=(V_{control gate}−V_{drain}−Vₜ). When programing, the Isat is a constant from external supply, so if V_{T} is lower and V_{control gate} is constant, then V_{drain} is increased. V_{gs} is the voltage across the gate and source. The reduced voltage difference results in a lower lateral electrical field between the source and drain regions of the flash cell device. The reduced lateral electric field results in less lateral diffusion of electrons and enables more efficient programming of the flash cell device.

FIG. 1 is a cross-sectional view showing floating gate region 100 and CMOS region 200 of substrate 2. Floating gate region 100 includes a multitude of floating gate transistors in some embodiments and the floating gate transistors form an array of memory cells in some embodiments. The floating gate transistors act as flash memory devices that store information in the array of memory cells.

Substrate 2 is a silicon substrate in some embodiments and in other embodiments, substrate 2 is formed of various other suitable semiconductor materials. In floating gate region 100, source 4 and drain 6 are formed within substrate 2 and are spaced apart by channel region 8. In operation, the roles of source 4 and drain 6 are used interchangeably. Channel region 8 includes a channel length between source 4 and drain 6, of about 500 nm to about 550 nm in various embodiments but in other embodiments, other channel lengths are used. Gate dielectric 10 is formed over substrate 2 and beneath floating gate electrode 12. Gate dielectric 10 is an oxide in some embodiments and gate dielectric 10 is a high-k dielectric in other embodiments and other suitable materials are used for gate dielectric 10 in still other embodiments. Gate dielectric 10 is formed to various thicknesses in various embodiments. Floating gate electrode 12 is formed of undoped polysilicon in some embodiments and floating gate 12 is formed of doped polysilicon in other embodiments and floating gate electrode 12 is formed of still other materials in other embodiments. Dielectric material 14 is disposed over floating gate electrode 12. Dielectric material 14 is an oxide in some embodiments but other materials are used in other embodiments. Dielectric material 14 takes on other shapes and other embodiments. Control gate dielectric 16 is disposed between floating gate electrode 12 and first material layer 18 over the top of floating gate electrode 12 and also along the opposed side edges of floating gate dielectrode 12. Control gate dielectric 16 is also disposed directly between first material layer 18 and substrate 2 in areas adjacent floating gate dielectric 12.

First material layer 18 is formed using chemical vapor deposition, CVD, in some embodiments. In other embodiments, first material layer 18 is formed using PVD (physical vapor deposition) operations such as sputtering or other suitable operations. First material layer 18 includes thickness 22. In some embodiments, thickness 22 is about 500 angstroms and in other embodiments, thickness 22 ranges from about 200 to about 2000 angstroms but still other thicknesses are used in other embodiments. The thickness is chosen in conjunction with other device features and in conjunction with a subsequent material layer formed thereover that will form a composite gate electrode material of a desired thickness for optimal device performance.

First material layer 18 is silicon-germanium in various embodiments. In various embodiments, the silicon-germanium represents any of various alloys including any molar ratio of silicon and germanium, as represented by Si₁₋ₓGeₓ. In still other embodiments, other suitable materials that provide a reduced depletion region in the control gate, such as such as suitable gate electrode metals Al, Ta, TaN, or Pt, are used for first material layer 18. The materials that provide a reduced depletion region in the control gate and which may be used for first material layer 18, may be collectively described as a depletion material layer.

The thicknesses and other dimensions provided herein are dimensions for compliance with design rules and for optimal manufacturability and device performance, and may vary in other embodiments.

Now referring to CMOS region 200 of FIG. 1, source 26 and drain 28 are formed within substrate 2 and CMOS channel region 30 extends between source 26 and drain 28. The roles of source 26 and drain 28 are interchangeable and depend upon the interconnect features of the various structures. First material layer 18 with thickness 22 is also formed within CMOS region 200. First material layer 18 is disposed over CMOS gate dielectric 34. In some embodiments, CMOS gate dielectric 34 is an oxide but other suitable gate dielectric materials are used in other embodiments.

CMOS gate dielectric 34 includes various thicknesses in various embodiments. In some embodiments, a single deposition or other formation operation is used to form first material layer 18 in both floating gate region 100 and CMOS region 200 simultaneously.

In some embodiments, first material layer 18 is then patterned and etched to remove first material layer 18 from CMOS region 200. Various patterning methods can be used. Various etching operations are used.

In some embodiments (not shown) first material layer 18 is not removed from CMOS region 200 and forms part of the CMOS transistor gate electrode.

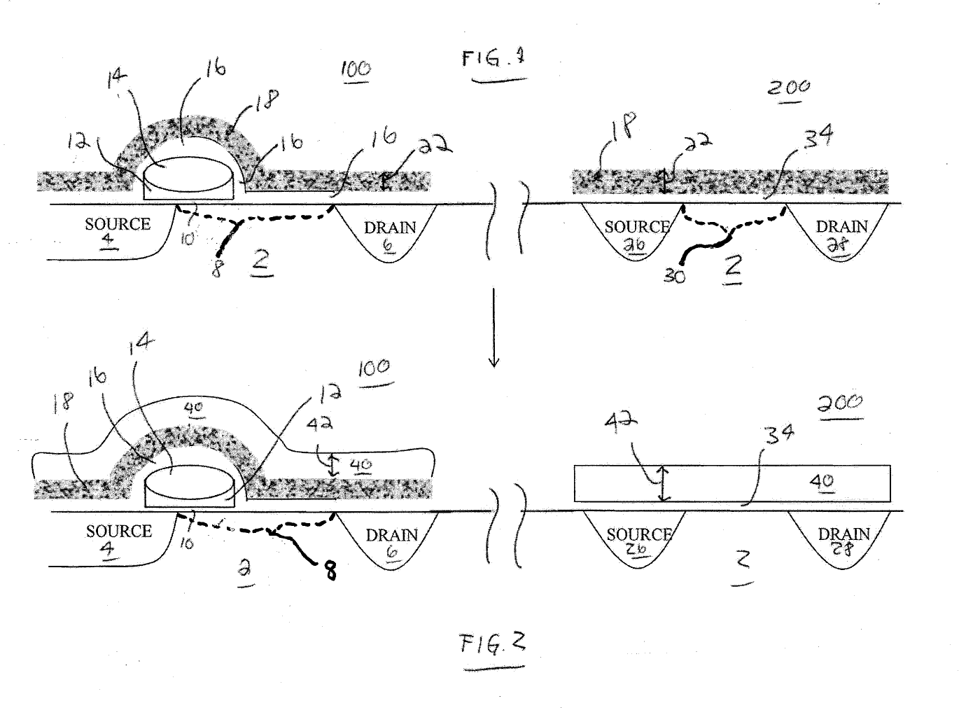

FIG. 2 shows the structures of FIG. 1 according to an embodiment in which the previously described patterning and etching operations have been carried out to remove first material layer 18 from CMOS region 200 and after second material layer 40 has been subsequently formed. Second material layer 40 combines with first material layer 18 to form a composite gate electrode material. Second material layer 40 forms an upper layer of a composite gate electrode material in floating gate region 100 and second material layer 40 forms the gate electrode in CMOS region 200.

In an embodiment, second material layer 40 is polysilicon, doped or undoped. In other embodiments, other suitable conductive or semiconductor materials are used for second material layer 40. Second material layer 40 includes thickness 42 which lies within the range of about 1500-2500 angstroms in some embodiments but other thicknesses are used in other embodiments. In an embodiment, thickness 42 is 2000 angstroms. Thickness 42 of second material layer 40 is chosen in conjunction with thickness 22 of first material layer 18 because in some embodiments, first material layer 18 and second material layer 40 combine to form a composite control gate electrode layer having a total desired thickness for optimal device operation and adherence to design rules.

Patterning and etching operations are then carried out to form the structures shown in FIG. 3 from the structures shown in FIG. 2.

FIG. 3 shows portions of transistor structures in both floating gate region 100 and CMOS region 200. In floating gate region 100, control gate electrode 46 includes a composite material including an upper layer of second material layer 40 and a lower layer of first material layer 18. The approximate relative thicknesses of second material layer 40 and first material layer 18 illustrated in FIG. 3, are not limiting and other relative thicknesses are used in other embodiments. In other embodiments, first material layer 18 occupies other locations within control gate electrode 46. Control gate electrode 46 is disposed over a portion of floating gate electrode 12 and also over a portion of substrate 2 in a region to the right-hand side adjacent floating gate electrode 12. Control gate dielectric 16 is disposed between control gate electrode 46 and the top of floating gate electrode 12. Control gate dielectric 16 is also disposed between control gate electrode 46 and one side of floating gate electrode 12. Control gate dielectric 16 is also disposed between control gate electrode 46 and substrate 2 as shown in FIG. 3. Floating gate transistor 50 includes overall channel length 48 which may range from about 500 nm to about 550 nm in various embodiments, and overall channel length 48 includes control gate length 60 and a portion of floating gate length 62. Control gate length 60 may range from about 300 nm to about 350 nm in various embodiments and floating gate length 62 may range from about 300 nm to about 350 nm in various embodiments but other dimensions are used in other embodiments.

Now referring to CMOS region 200 of FIG. 3, CMOS transistor 52 includes CMOS gate electrode 54 formed of second material layer 40. Various suitable channel lengths and other dimensions are used. In some embodiments, CMOS gate electrode 54 also includes portions of first material layer 18.

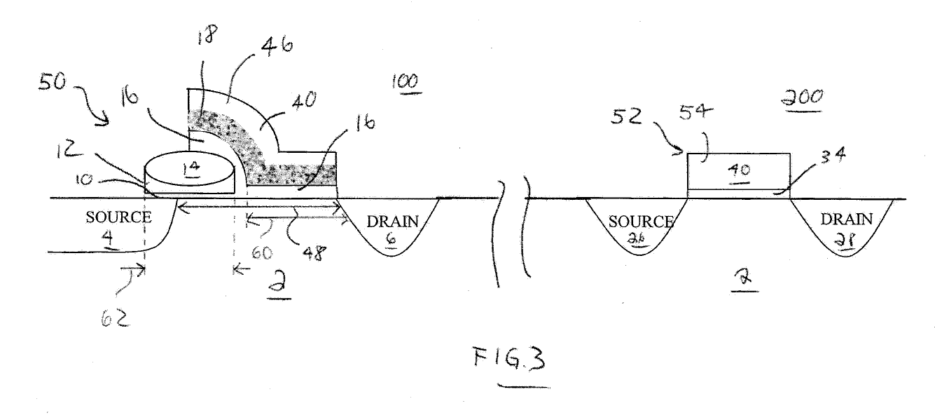

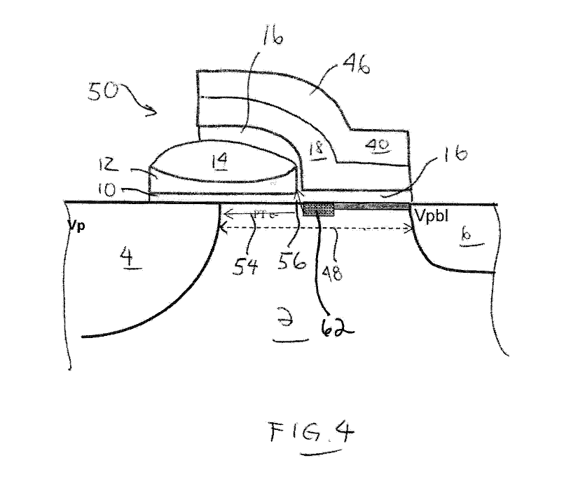

FIG. 4 shows floating gate transistor 50 in further detail. Control gate electrode 46 is coupled to a word line in operation, in some embodiments and voltage V_{pwl} is applied to the word line and therefore the control gate electrode 46 in some embodiments. In some embodiments, drain 6 is coupled to a bit line in operation, and includes voltage V_{pbl}. Pinch off voltage Vₚ is applied to source 4 in operation, in some embodiments. The threshold voltage of transistor 50 is partially determined by the electrical characteristics and physical properties of control gate. 46. When V_{pwl} is greater than Vₜ, the channel (channel region 8) under the control gate is turned on to allow electron flow in the channel.

The control gate electrode 46 with reduced depletion due to the presence of first material layer 18 enables the use of a lower threshold voltage, Vₜ for programming to obtain the programming current, Iprog. Because V_{pbl} is increased as a result of the increased depletion mode of the control gate electrode 46 according to the disclosure, the programming current can be achieved using a lower Vₜ according to the following equation:

Iprog=Idsat=W/2L*u*(A [symbol] /dox)*[V_{pwl}−V_{pbl}−Vₜ]²

The use of a lower threshold voltage, Vₜ, reduces the likelihood of problems associated with an elevated Vₜ For example, problems such as leakage are obviated. The increase in the V_{pbl} results in the difference between Vₜ and V_{pbl} being reduced. This produces a reduced lateral electric field between the source 4 and drain 6 areas. The reduced electric field between source 4 and drain 6 reduces lateral electron diffusion such as may otherwise occur along a direction indicated by arrow 54 and allows a greater number of hot electrons as indicated by arrow 56, to be attracted to the floating gate from a region 62 in channel region 8. This, in turn, improves the flash gate programming efficiency.

According to an embodiment, a split-gate flash cell device comprises a floating gate disposed over a gate dielectric disposed on a substrate; and a control gate disposed over a portion of the floating gate and being a composite material including a first layer and a further layer, the first layer including a depletion material layer.

In some embodiments, the first layer includes at least silicon and germanium and is a lower layer, and the further layer is an upper layer.

In some embodiments, the first layer is an SiGe layer and is a lower layer, and the further layer is an upper layer comprising polysilicon.

In some embodiments, the first layer comprises Si₁₋ₓGeₓ and is a lower layer and the further layer is an upper layer and the control gate further includes a further section disposed over a portion of the substrate adjacent the floating gate.

In some embodiments, the further section is disposed on a dielectric disposed on the substrate.

In some embodiments, the further section is adjacent a first of opposed ends of the floating gate and the split-gate flash cell device further comprises a source/drain region in the substrate adjacent an end of the further section and a further source/drain section in the substrate adjacent the other of the opposed ends of the floating gate.

In some embodiments, the first layer comprises one of Al, Ta, TaN, and Pt and is a lower layer, and the further layer is an upper layer.

In some embodiments, the split-gate flash cell device further comprises a control gate dielectric disposed between the floating gate and the control gate.

In some embodiments, the control gate further includes a further section disposed over a portion of the substrate adjacent the floating gate and the control gate dielectric is disposed between an upper most surface of the floating gate and the control gate and also between the control gate and a side surface of the floating gate.

In some embodiments, the first layer comprises Si₁₋ₓGeₓ and is a lower layer of the control gate and includes a thickness within a range of about 400-600 angstroms, and the further layer is an upper layer is formed of polysilicon and includes a thickness within a range of about 1500-2500 angstroms.

In some embodiments, the control gate is coupled to a word line and the floating gate is formed of silicon and includes a thickness in a range of about 800-1300 angstroms.

In another aspect, a split-gate flash cell device comprises a floating gate electrode disposed over a gate dielectric disposed on a substrate; a control gate disposed over a portion of the floating gate and over a portion of the substrate adjacent the floating gate electrode and including as part thereof; and a control gate dielectric disposed between the floating gate electrode and the control gate.

In some embodiments, the control gate includes a composite material including a lower layer of the Si₁₋ₓGeₓ and an upper layer.

In some embodiments, the floating gate electrode is formed of doped or undoped polysilicon.

In some embodiments, the control gate dielectric is also disposed between the control gate and the portion of the substrate adjacent the floating gate electrode.

In some embodiments, the control gate includes a composite material including a lower layer of the Si₁₋ₓGeₓ and an upper layer of polysilicon.

In another aspect, a method for forming a split-gate flash cell is provided. The method comprises forming a floating gate over a gate dielectric disposed over a substrate; and forming a composite control gate material by first depositing a layer of Si₁₋ₓGeₓ then depositing a further layer over the layer of Si₁₋ₓGeₓ then patterning the composite control gate material to form a control gate over a portion of the floating gate and over a portion of the substrate adjacent the floating gate.

In some embodiments, the further layer comprises polysilicon.

In some embodiments, the method further comprises simultaneously forming CMOS transistors over the substrate in CMOS sections, including forming CMOS transistor gates by removing the layer of Si₁₋ₓGeₓ from the CMOS sections and patterning the further layer to form the CMOS transistor gates.

In some embodiments, the method further comprises simultaneously forming CMOS transistors over the substrate in CMOS sections.

In some embodiments, the first depositing a layer of Si₁₋ₓGeₓ comprises chemical vapor deposition, and wherein the forming of floating gate comprises depositing and etching a doped polysilicon material.

The preceding merely illustrates the principles of the disclosure. It will thus be appreciated that those of ordinary skill in the art will be able to devise various arrangements which, although not explicitly described or shown herein, embody the principles of the disclosure and are included within its spirit and scope. Furthermore, all examples and conditional language recited herein are principally intended expressly to be only for pedagogical purposes and to aid the reader in understanding the principles of the disclosure and the concepts contributed by the inventors to furthering the art, and are to be construed as being without limitation to such specifically recited examples and conditions. Moreover, all statements herein reciting principles, aspects, and embodiments of the disclosure, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the disclosure has been described in terms of exemplary embodiments, it is not limited thereto. Rather, the appended claims should be construed broadly, to include other variants and embodiments of the disclosure, which may be made by those of ordinary skill in the art without departing from the scope and range of equivalents of the disclosure.

What is claimed is:

1. A split-gate flash cell device comprising:
a floating gate disposed over a gate dielectric disposed on a substrate; and
a control gate disposed over a portion of the floating gate and being a composite material including a first layer and a further layer, said first layer including a depletion material layer.

2. The split-gate flash cell device as in claim 1, wherein the first layer includes at least silicon and germanium and is a lower layer, and the further layer is an upper layer.

3. The split-gate flash cell device as in claim 1, wherein the first layer is an SiGe layer and is a lower layer, and the further layer is an upper layer comprising polysilicon.

4. The split-gate flash cell device as in claim 1, wherein the first layer comprises Si₁₋ₓGeₓ and is a lower layer and the further layer is an upper layer and the control gate further includes a further section disposed over a portion of the substrate adjacent the floating gate.

5. The split-gate flash cell device as in claim 4, wherein the further section is disposed on a dielectric disposed on the substrate.

6. The split-gate flash cell device as in claim 4, wherein the further section is adjacent a first of opposed ends of the floating gate and further comprising a source/drain region in the substrate adjacent an end of the further section and a further source/drain section in the substrate adjacent the other of the opposed ends of the floating gate.

7. The split-gate flash cell device as in claim 1, wherein the first layer comprises one of Al, Ta, TaN, and Pt and is a lower layer, and the further layer is an upper layer.

8. The split-gate flash cell device as in claim 1, further comprising a control gate dielectric disposed between the floating gate and the control gate, wherein the control gate includes a further section disposed over a portion of the substrate adjacent the floating gate and the control gate dielectric is disposed between an uppermost surface of the floating gate and the control gate and further between the control gate and a side surface of the floating gate.

9. The split-gate flash cell device as in claim 1, wherein the first layer comprises Si₁₋ₓGeₓ and is a lower layer of the control gate and includes a thickness within a range of about 400-600 angstroms and the further layer is an upper layer is formed of polysilicon and includes a thickness within a range of about 1500-2500 angstroms.

10. The split-gate flash cell device as in claim 1, wherein the control gate is coupled to a word line and the floating gate is formed of silicon and includes a thickness in a range of about 800-1300 angstroms.

11. A split-gate flash cell device comprising:
a floating gate electrode disposed over a gate dielectric disposed on a substrate;
a control gate disposed over a portion of the floating gate and over a portion of the substrate adjacent the floating gate electrode and including Si₁₋ₓGeₓ as part thereof; and
a control gate dielectric disposed between the floating gate electrode and the control gate.

12. The split-gate flash cell device as in claim 11, wherein the control gate includes a composite material including a lower layer of the Si₁₋ₓGeₓ and an upper layer.

13. The split-gate flash cell device as in claim 11, wherein the floating gate electrode is formed of doped or undoped polysilicon.

14. The split-gate flash cell device as in claim 11, wherein the control gate dielectric is also disposed between the control gate and the portion of the substrate adjacent the floating gate electrode.

15. The split-gate flash cell device as in claim 11, wherein the control gate includes a composite material including a lower layer of the Si₁₋ₓGeₓ and an upper layer of polysilicon.

16. A method for forming a split-gate flash cell, the method comprising:
forming a floating gate over a gate dielectric disposed over a substrate; and
forming a composite control gate material by first depositing a layer of Si₁₋ₓGeₓ then depositing a further layer over the layer of Si₁₋ₓGeₓ then patterning the composite control gate material to form a control gate over a portion of the floating gate and over a portion of the substrate adjacent the floating gate.

17. The method as in claim 16, wherein the further layer comprises polysilicon.

18. The method as in claim 17, further comprising simultaneously forming CMOS transistors over the substrate in CMOS sections, including forming CMOS transistor gates by removing the layer of Si₁₋ₓGeₓ from the CMOS sections and patterning the further layer to form CMOS transistor gates.

19. The method as in claim 17, further comprising simultaneously forming CMOS transistors over the substrate in CMOS sections.

20. The method as in claim 17, wherein the first depositing a layer of Si₁₋ₓGeₓ comprises chemical vapor deposition, and wherein the forming of floating gate comprises depositing and etching a doped polysilicon material.
